(19) United States
(12) Patent Application Publication
(10) Pub. No.: US 2025/0261447 A1
(43) Pub. Date: Aug. 14, 2025

(54) SEMICONDUCTOR DEVICE

(71) Applicant: Japan Display Inc., Tokyo (JP)

(72) Inventor: Toshihiko ITOGA, Tokyo (JP)

(73) Assignee: Japan Display Inc., Tokyo (JP)

(21) Appl. No.: 19/033,539

(22) Filed: Jan. 22, 2025

(30) Foreign Application Priority Data
Feb. 9, 2024 (JP) 2024-018936

(51) Int. Cl. H10D 86/40; H10D 30/67

(52) U.S. Cl. CPC H10D 86/451; H10D 30/6706; H10D 30/6723; H10D 86/471

(57) ABSTRACT

A semiconductor device includes a glass substrate, a base layer on the glass substrate, and a thin film transistor on the base layer, wherein the base layer has a structure in which a first insulating layer made of silicon oxide, a second insulating layer made of silicon nitride, a conductive layer, and a third insulating layer made of silicon oxide are stacked in this order from the glass substrate side. The base layer may have a fourth insulating layer made of silicon oxide between the second insulating layer and the conductive layer.

### CROSS-REFERENCE TO RELATED APPLICATION

This application claims the benefit of priority to Japanese Patent Application No. 2024-018936, filed on Feb. 9, 2024, the entire contents of which are incorporated herein by reference.

### FIELD

The present invention relates to a semiconductor device in which a thin film transistor is arranged on a glass substrate.

### BACKGROUND

A semiconductor device including a thin film transistor in which a semiconductor layer such as polysilicon is formed on a glass substrate is known. In such a semiconductor device, for example, as disclosed in Japanese laid-open patent publication No. 2005-252188, a base layer is formed on the glass substrate.

The semiconductor device disclosed in Japanese laid-open patent publication No. 2005-252188 has a structure in which an insulating layer selected from silicon oxide, silicon nitride, silicon oxynitride, and the like and a light-shielding layer made of titanium are stacked in a part corresponding to a base layer of the thin film transistor.

Silicon nitride in the base layer of the semiconductor device has excellent properties as a barrier film, but it is known that charge traps are formed in the film and on the interface of the base layer.

### SUMMARY

A semiconductor device according to an embodiment of the present invention includes a glass substrate, a base layer on the glass substrate, and a thin film transistor on the base layer, wherein the base layer has a structure in which a first insulating layer made of silicon oxide, a second insulating layer made of silicon nitride, a conductive layer, and a third insulating layer made of silicon oxide are stacked in this order from the glass substrate side.

### BRIEF DESCRIPTION OF DRAWINGS

FIG. 1 is a cross-sectional view showing an outline of a semiconductor device according to a first embodiment of the present invention.

FIG. 2 is a cross-sectional view showing an outline of a semiconductor device according to other embodiments of the present invention.

FIG. 3 is a cross-sectional view showing an outline of a semiconductor device according to a second embodiment of the present invention.

FIG. 4 is a graph showing Vg-Id properties of a semiconductor device of Example 1.

FIG. 5 is a graph showing Vg-Id properties of a semiconductor device of Reference Example 1.

FIG. 6 is a graph showing Vg-Id properties of a semiconductor device of Example 2.

FIG. 7 is a graph showing Vg-Id properties of a semiconductor device of Reference Example 2.

### DESCRIPTION OF EMBODIMENTS

Hereinafter, embodiments of the present invention will be described with reference to the drawings. In some cases, the width, thickness, shape, and the like of each part are schematically represented in comparison with the actual embodiments in order to clarify the description, but the drawings are merely examples and do not limit the interpretation of the present invention. In the present specification and the drawings, the same reference signs are given to elements similar to those described above with respect to the above-described drawings, and detailed description thereof may be omitted as appropriate.

### First Embodiment

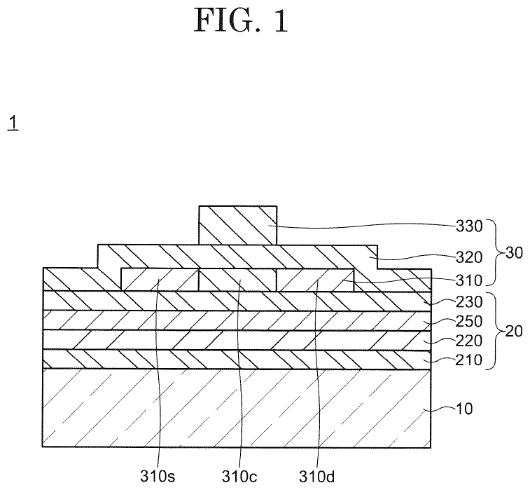

A semiconductor device 1 according to a first embodiment of the present invention will be described. FIG. 1 is a cross-sectional view schematically showing the semiconductor device 1. As shown in FIG. 1, the semiconductor device 1 includes a glass substrate 10, a base layer 20, and a thin film transistor 30 in this order.

The glass substrate 10 is used as the substrate for the semiconductor device 1 from the viewpoint of the strength.

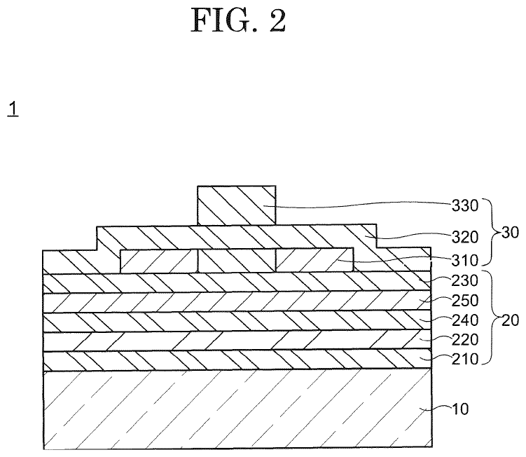

The base layer 20 is formed on the glass substrate 10. The base layer 20 has a structure in which a first insulating layer 210, a second insulating layer 220, a conductive layer 250, and a third insulating layer 230 are stacked from the glass substrate 10 side. The second insulating layer 220 is formed on the first insulating layer 210 and is in contact with the first insulating layer 210. The conductive layer 250 is formed on the second insulating layer 220 and is in contact with the second insulating layer 220. The third insulating layer 230 is formed on the conductive layer 250 and is in contact with the conductive layer 250. The layer structure of the base layer 20 is not limited to this. For example, as shown in FIG. 2, the base layer 20 may have a fourth insulating layer 240 between the second insulating layer 220 and the conductive layer 250 from the viewpoint of the insulating properties in the semiconductor device 1.

The first insulating layer 210 and the third insulating layer 230 are made of silicon oxide (SiO₂). The second insulating layer 220 is made of silicon nitride (SiNₓ). For example, the first insulating layer 210, the second insulating layer 220, and the third insulating layer 230 are formed using a plasma CVD method. Silicon oxide has excellent compatibility with a semiconductor layer 310. Silicon nitride has excellent ion blocking properties. In the case where the base layer 20 further has an insulating layer, such as the fourth insulating layer 240, the insulating layer is made of silicon oxide, silicon nitride, silicon oxynitride, or the like, and is formed using the plasma CVD method.

For example, the conductive layer 250 is made of a metal such as titanium, aluminum, tantalum, molybdenum, tungsten, or an alloy thereof. For example, the conductive layer 250 is formed using a sputtering method. The conductive layer 250 may be referred to as a light-shielding layer because it may block light entering the thin film transistor 30 from the glass substrate 10 side.

The thin film transistor 30 has a structure in which the semiconductor layer 310, a gate insulating layer 320, and a gate electrode layer 330 are stacked in this order from the base layer 20 side. The semiconductor layer 310 is formed on the base layer 20 and is in contact with the base layer 20. The gate insulating layer 320 is formed on the semiconductor layer 310 and is in contact with the semiconductor layer 310. The gate electrode layer 330 is formed on the gate insulating layer 320 and is in contact with the gate insulating layer 320.

For example, the semiconductor layer 310 is made of amorphous silicon or polysilicon, and is made of an oxide semiconductor made of an oxide such as indium, gallium, or zinc. For example, the semiconductor layer 310 is formed using the sputtering method or the plasma CVD method. In the case where the semiconductor layer 310 is made of polysilicon, the semiconductor layer 310 may be formed by performing a heat treatment by laser irradiation or the like on the amorphous silicon deposited on the base layer 20.

In a cross-sectional view, the semiconductor layer 310 has a channel region 310c formed in a region overlapping the gate electrode layer 330. The semiconductor layer 310 has a region extending outwardly from the region overlapping the gate electrode layer 330. A source region 310s and a drain region 310d doped with an n-type impurity or p-type impurity are formed on both sides of the channel region 310c of the semiconductor layer 310. For this reason, the semiconductor layer 310 includes the source region 310s, the channel region 310c, and the drain region 310d in its layer. When the n-type impurities are doped, the thin film transistor 30 becomes an n-channel type thin film transistor 30n. When the p-type impurities are doped, the thin film transistor 30 becomes a p-channel type thin film transistor 30p.

For example, the gate insulating layer 320 is made of silicon oxide. For example, the gate insulating layer 320 is formed using the plasma CVD method.

For example, the gate electrode layer 330 is made of a metal such as aluminum, tantalum, molybdenum, or an alloy thereof. For example, the gate electrode layer 330 is formed using the sputtering method.

In a conventional semiconductor device, the base layer may be made of three layers of a first insulating layer made of silicon oxide, a second insulating layer made of silicon nitride, and a third insulating layer made of silicon oxide. In this case, positive fixed charges may be present due to a charge trap in the second insulating layer made of silicon nitride, at an interface between the first insulating layer and the second insulating layer in the second insulating layer, and at an interface between the second insulating layer and the third insulating layer in the second insulating layer. The semiconductor layer is affected by this fixed charge, and a threshold voltage (Vth) of the semiconductor device is shifted to the negative side. In this case, an n-channel transistor changes to a normally on state (a drain current flows between the source and the drain even when no voltage is applied to a gate electrode). In order to prevent the n-channel transistor from being normally on state, a method in which the semiconductor layer is doped with the p-type impurity (acceptor impurity) has been adopted. That is, in the case where the thin film transistor is the n-channel transistor, the semiconductor layer is doped with the p-type impurity in order to reduce the influence of the fixed charge. Doping of the p-type impurity is performed by an ion implantation method. Since the ion implantation method is a method in which the p-type impurity is accelerated by an electric field and implanted into the semiconductor layer, if the dose of the p-type impurity is large, ion implantation damage occurs, resulting in a decrease in a field-effect mobility.

On the other hand, according to the semiconductor device 1 according to the first embodiment of the present invention, since the conductive layer 250 is arranged between the second insulating layer 220 in which the positive fixed charge is present and the semiconductor layer 310 affected by the positive fixed charge, the influence of the positive fixed charge can be prevented by the conductive layer 250. Therefore, the threshold voltage (Vth) of the thin film transistor 30 is optimized. That is, even if the fixed charge is accumulated in the film of the second insulating layer 220 made of silicon nitride forming the base layer 20 and at the interface between the upper and lower layers, the electric field due to the fixed charge is shielded by the interposition of the conductive layer 250 between the second insulating layer 220 and the semiconductor layer 310, and the negative shift of the threshold voltage (Vth) of the thin film transistor 30 can be suppressed. As a result, the dose of the p-type impurity doped into the semiconductor layer 310 can be reduced, and the decrease in the field-effect mobility can be suppressed.

### Second Embodiment

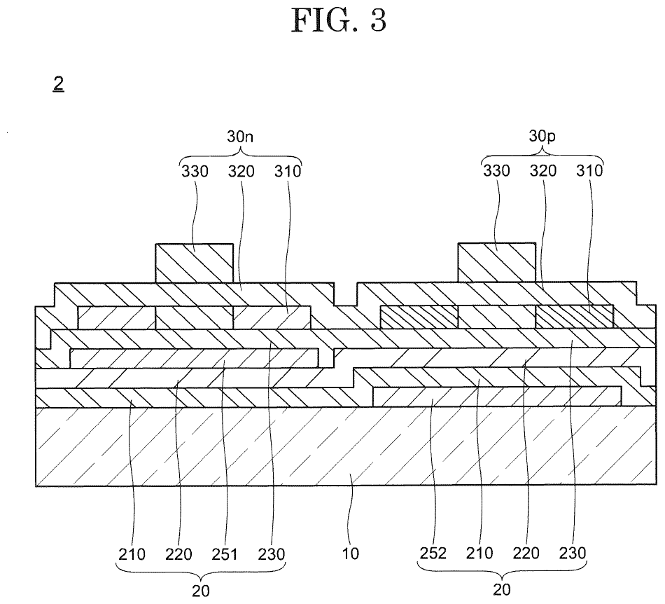

A semiconductor device 2 according to a second embodiment of the present invention will be described. FIG. 3 is a cross-sectional view schematically showing the semiconductor device 2. As shown in FIG. 3, the semiconductor device 2 includes the glass substrate 10, the base layer 20, and the n-channel type thin film transistor 30n and the p-channel type thin film transistor 30p on the base layer 20. The glass substrate 10, the base layer 20, the n-channel type thin film transistor 30n, and the p-channel type thin film transistor 30p are configured in the same manner as in the first embodiment, and can be formed in the same manner.

The base layer 20 has a structure in which the first insulating layer 210 made of silicon oxide, the second insulating layer 220 made of silicon nitride, and the third insulating layer 230 made of silicon oxide are stacked in this order from the glass substrate 10 side. The layer structure of the base layer 20 is not limited to this. For example, from the viewpoint of the insulating properties of the semiconductor device 2, the fourth insulating layer 240 may be further arranged.

In a cross-sectional view, the base layer 20 includes a first light-shielding layer 251 that overlaps the n-channel type thin film transistor 30n between the second insulating layer 220 and the third insulating layer 230. The first light-shielding layer 251 is conductive. On the other hand, in a cross-sectional view, the base layer 20 on which the p-channel type thin film transistor 30p overlaps does not have a conductive layer between the second insulating layer 220 and the semiconductor layer 310, and has a second light-shielding layer 252 on which the p-channel type thin film transistor 30p overlaps between the glass substrate 10 and the first insulating layer 210. In addition, the base layer 20 on which the p-channel type thin film transistor 30p overlaps may not have the second light-shielding layer 252.

According to the semiconductor device 2 according to the second embodiment of the present invention, in a cross-sectional view, the base layer 20 on which the n-channel type thin film transistor 30n overlaps has the conductive first light-shielding layer 251 between the second insulating layer 220 and the third insulating layer 230, so that the influence of the positive fixed charge present in the second insulating layer 220 can be blocked by the first light-shielding layer 251. On the other hand, in a cross-sectional view, the base layer 20 on which the p-channel type thin film transistor 30p overlaps has no conductive layer between the second transistor 220 and the semiconductor layer 310, and is therefore affected by the positive fixed charge present in the second transistor 220. According to this configuration, even if the impurity doping amounts of the n-channel type thin film transistor 30n and the p-channel type thin film transistor 30p are the same, Vth between the n-channel type thin film transistor 30n and the p-channel type thin film transistor 30p becomes substantially the same, so that Vth as the semiconductor device 2 can be optimized.

### EXAMPLES

The present invention will be described in detail using Examples below, but the present invention is not limited to these Examples.

### Example 1

A semiconductor device of Example 1 is composed of a glass substrate, a base layer (a first insulating layer, a second insulating layer, a fourth insulating layer, a conductive layer, and a third insulating layer), and an n-channel type thin film transistor (a semiconductor layer, a gate insulating layer, and a gate electrode layer). A first insulating layer made of silicon oxide having a thickness of 500 nm, a second insulating layer made of silicon nitride having a thickness of 50 nm, and a fourth insulating layer made of silicon oxide having a thickness of 50 nm were formed in this order on the glass substrate having a thickness of 0.5 mm. A conductive layer made of an alloy of molybdenum and tungsten having a thickness of 50 nm was formed on the fourth insulating layer. The third insulating layer made of silicon oxide having a thickness of 200 nm was formed on the conductive layer. A semiconductor layer made of polysilicon was formed on the third insulating layer and doped with the n-type impurity. A gate insulating layer made of silicon oxide having a thickness of 100 nm and a gate electrode layer made of MoW having a thickness of 250 nm were formed in this order on the semiconductor layer.

### Reference Example 1

A semiconductor device of Reference Example 1 is composed of a glass substrate, a base layer (a first insulating layer, a second insulating layer, a fourth insulating layer, and a third insulating layer), and an n-channel type thin film transistor (a semiconductor layer, a gate insulating layer, and a gate electrode layer). The semiconductor device of Reference Example 1 was manufactured in the same manner as the semiconductor device of Example 1 except that the conductive layer was not formed.

### Example 2

A semiconductor device of Example 2 is composed of a glass substrate, a base layer (a first insulating layer, a second insulating layer, a fourth insulating layer, a conductive layer, and a third insulating layer), and a p-channel type thin film transistor (a semiconductor layer, a gate insulating layer, and a gate electrode layer). The semiconductor device of Example 2 was manufactured in the same manner as the semiconductor device of Example 1 except that the same amount of p-type impurities was doped instead of the n-type impurity.

### Reference Example 2

A semiconductor device of Reference Example 2 is composed of a glass substrate, a base layer (a first insulating layer, a second insulating layer, a fourth insulating layer, and a third insulating layer), and p-channel type thin film transistor (a semiconductor layer, a gate insulating layer, and a gate electrode layer). The semiconductor device of Reference Example 2 was manufactured in the same manner as the semiconductor device of Example 2 except that the conductive layer was not formed.

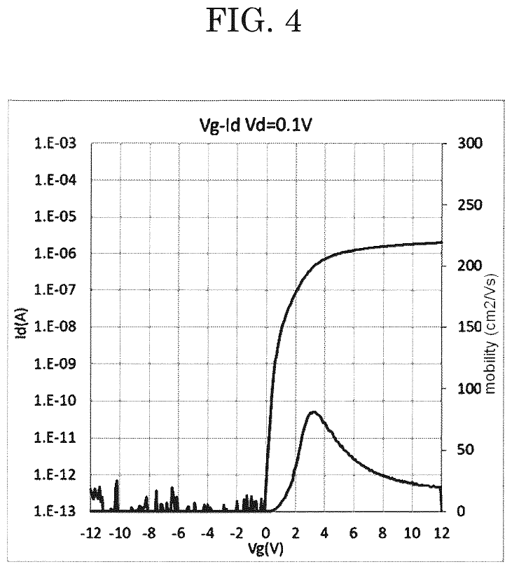

For the semiconductor devices of Example 1, Reference Example 1, Example 2, and Reference Example 2, the Vg-Id properties were measured when the drain-source voltage (Vd) was set to 0.1 V. Graphs of the Vg-Id properties of the semiconductor devices of Example 1, Reference Example 1, Example 2, and Reference Example 2 are shown in FIG. 4 to FIG. 7, respectively.

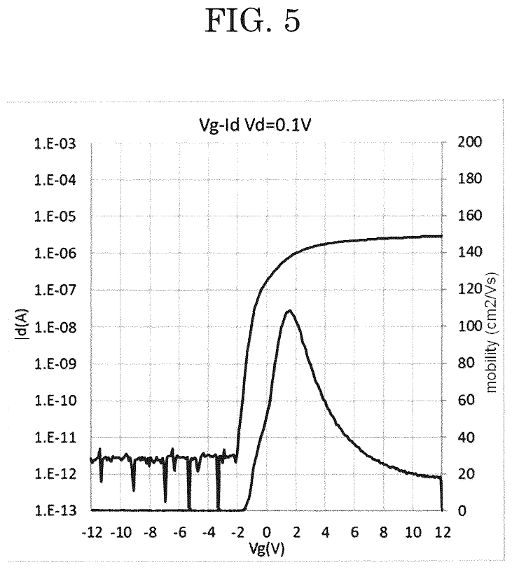

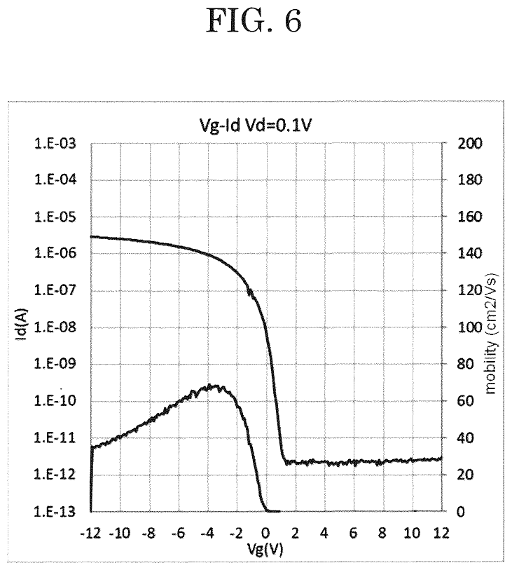

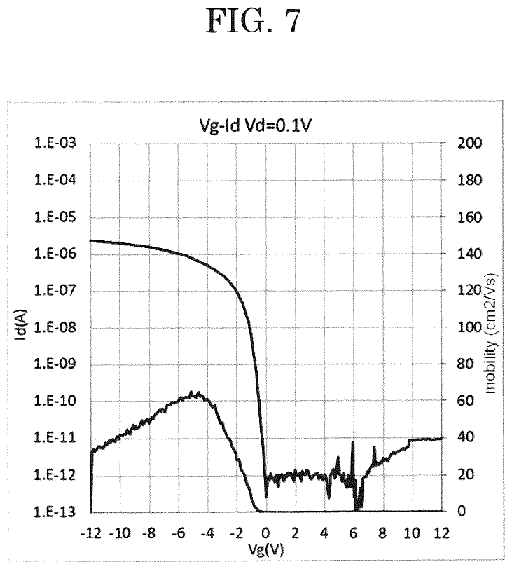

As shown in FIG. 4 and FIG. 5, in the semiconductor device made of the n-channel type thin film transistor, by arranging the conductive layer between the second insulating layer and the semiconductor layer, the influence of the positive fixed charge present in the second insulating layer was prevented, and Vth of the semiconductor device was shifted to the positive side by about 2 V, thereby making it possible to optimize Vth. In addition, as shown in FIG. 6 and FIG. 7, in the semiconductor device made of the p-channel type thin film transistor, by arranging the conductive layer between the second insulating layer and the semiconductor layer, the influence of the positive fixed charge present in the second insulating layer was prevented, and Vth of the semiconductor device was shifted to the positive side by about 1 V, thereby making it possible to optimize Vth.

In addition, as shown in FIG. 4 and FIG. 7, in the semiconductor device made of the n-channel type thin film transistor, the conductive layer is arranged between the second insulating layer and the semiconductor layer, and in the semiconductor device made of the p-channel type thin film transistor, the conductive layer is not arranged between the second insulating layer and the semiconductor layer, so that Vth of the n-channel type thin film transistor and the p-channel type thin film transistor becomes substantially the same even when the impurity doping amounts of the n-channel type thin film transistor and the p-channel type thin film transistor are the same, thereby making it possible to optimize Vth as the semiconductor device.

It is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a glass substrate;
a base layer on the glass substrate; and
a thin film transistor on the base layer, wherein
the base layer has a structure in which a first insulating layer including silicon oxide, a second insulating layer including silicon nitride, a conductive layer, and a third insulating layer including silicon oxide are stacked in this order from the glass substrate side.

2. The semiconductor device according to claim 1, wherein the conductive layer includes a metal.

3. The semiconductor device according to claim 2, wherein the base layer includes a fourth insulating layer including silicon oxide between the second insulating layer and the conductive layer.

4. A semiconductor device comprising:
a glass substrate;
a base layer on the glass substrate; and
an n-channel type thin film transistor and a p-channel type thin film transistor on the base layer, wherein
the base layer has a structure in which a first insulating layer including silicon oxide, a second insulating layer including silicon nitride, and a third insulating layer including oxide are stacked in this order from the glass substrate side,
the base layer includes a first light-shielding layer overlapping the n-channel type thin film transistor, and
the first light-shielding layer is conductive and is arranged between the second insulating layer and the third insulating layer.

5. The semiconductor device according to claim 4, wherein the base layer includes a second light-shielding layer overlapping the p-channel type thin film transistor, and
the second light-shielding layer is arranged between the substrate and the first insulating layer.
